(19) United States
(12) Patent Application Publication
(10) Pub. No.: US 2011/0083696 A1
(43) Pub. Date: Apr. 14, 2011

(54) Laser Induced Shockwave Surface Cleaning

(75) Inventors: Waleed Nasr, Valencia, CA (US); Khaled Nasr, Los Angeles, CA (US)

(73) Assignee: Nuventys Inc.

(21) Appl. No.: 12/896,434

(22) Filed: Oct. 1, 2010

Related U.S. Application Data
(60) Provisional application No. 61/278,628, filed on Oct. 8, 2009.

(51) Int. Cl. C25F 1/00; H01L 21/306

(52) U.S. Cl. 134/1.1; 156/345.5

(57) ABSTRACT

An apparatus and method for cleaning the surface of a substrate using laser-induced plasma shockwaves and ultraviolet radiation is described. After defects such as organic, inorganic and metallic particles are detected during an inspection step, the substrate is mounted on a motorized stage inside a cleaning chamber. A laser beam is focused into a laser-cleaning nozzle within the chamber. The laser energy generates a laser-induced plasma shockwave inside the nozzle. The shockwave is amplified and exits the nozzle generating the necessary force to overcome the adhesion bond of the defects with the substrate. Coordinating defect locations from the preliminary inspection step the substrate is actively positioned only where defects are present for selective removal.

### CROSS-REFERENCE TO RELATED APPLICATIONS

This application is a non-provisional application describing the same invention as an active provisional application, Ser. No. 61/278,628, filed on Oct. 8, 2009, and being filed within one year, hereby claims date priority therefrom. Said provisional application is incorporated herein by reference in its entirety.

### TECHNICAL FIELD AND BACKGROUND

The present description relates to surface cleaning, and more particularly, to a method and apparatus for non-contact laser induced shockwave treatment of contaminates on a substrate, such as, a semiconductor wafer or photomask for example. The terms “shock” and “wave” are used in combination herein as a single term “shockwave” to mean a traveling shock wave, that is a wave of energy that has a significant energy impulse. There are currently numerous methods used to clean substrate surfaces in the semiconductor industry including both chemical and mechanical cleaning techniques. For example, wet cleaning, megasonic and ultrasonic cleaning, brush cleaning, supercritical fluid cleaning and wet laser cleaning are all used to clean particles from the surface of a substrate. However, for sub-micron particulate these cleaning processes are ineffective as each has serious drawbacks requiring the use of cleaning tools and chemical agents that may introduce new contaminates or which may damage critical dimensions of a semiconductor or mask device. Furthermore, each of the above cleaning processes is directed to cleaning the entire surface of the substrate thereby increasing the probability of redeposition and damaging the substrate surface.

In conventional cleaning of substrates, a wet cleaning method commonly referred to by the term “RCA cleaning” uses large-scale multi-tank immersion cleaning units. This procedure has been used for many years. In this technique, up to 50 substrates are immersed sequentially in aqueous solutions of: ammonium hydroxide plus hydrogen peroxide, hydrochloric acid plus hydrogen peroxide, and dilute heated hydrofluoric acid so as to remove particles, metallic contamination, and organic contamination. After each chemical processing step, the substrates are rinsed in pure water. Since this process uses a large amount of environmentally undesirable and expensive chemicals, and is not especially effective for smaller substrate features, alternative cleaning approaches are needed.

Megasonic or ultrasonic cleaning removes organic films and particles from a photomask surface by the application of hydrostatic forces created in combination with the action of a chemical solution. However, both megasonic and ultrasonic cleaning techniques operate on the principle of chemical immersion which, undesirably, treats the entire substrate surface.

Wet laser cleaning is also used to clean substrate surfaces. This cleaning technique entails cleaning the surface with a liquid, such as water or water and alcohol, wherein the solution is super-heated using a laser pulse as the heat source. In so doing, the solution rapidly expands propelling particle from a substrate surface. In this approach, the liquid solution can penetrate metal lines on a patterned substrate which can cause lifting of the metal lines off the substrate causing damage to the pattern and generating additional particulate.

Relative larger lasers (600 mJ or greater) have been used to generate a laser induced plasma in air. These larger lasers generate radiation heat from the core of the laser induced plasma in excess of 15,000 K. In the case of laser induced plasma in air, the distance at which the radiation temperature drops below 1000 K is 1.5 to 5 mm from the center of the plasma core for I=1.3×10¹³ and 2.3×10¹⁴ W/cm2, respectively. The radiation heating from the laser induced plasma core can induce a considerable temperature rise on the substrate surface damaging thin films and sensitive structures.

Other cleaning techniques include those that employ momentum transfer as a means to impinge and dislodge defects or contaminants from a surface. For example cryogenic aerosol cleaning uses pressurized frozen particles to remove surface contamination. Momentum transfer cleaning techniques are problematic for future generations of semiconductor technology as they increase the risk of physical damage to a substrate surface. Cryogenic cleaning can also electro-statically damage a surface of a substrate due to the presence of ions in the cleaning fluid.

As manufacturers continue to decrease feature size, the need for, and cost of removal of substrate contamination grows. A more effective and efficient cleaning method and apparatus for removing contaminants from semiconductor and optics industry work products is needed.

### SUMMARY

The present apparatus and method provides a novel and greatly improved means for removing sub-micron particulate contamination from critical surfaces. The method employs a laser beam focused in a gaseous environment which results in a dielectric breakdown and ionization of the gas generating a rapidly expanding plasma at the focal point of the laser beam. Initially a release of electrons occurs due to the collision of photons with gas molecules. This creates a local high pressure plasma forming a shockwave which moves outward at supersonic velocity. With a Nd:YAG pulsed laser, these actions occur approximately in the first 100-150 ns of the arrival of the laser pulse at the focal point. The shockwave separates from the plasma within the first few microseconds of the process.

The shockwave plays a critical role in breaking the bonds which hold particles to a substrate. A force moment is exerted on the particles due to collisions of those gas molecules which are adjacent to the particles, with the particles, the collisions delivering energy from the shockwave to the particles. The interaction of the shockwave energy with the substrate is a momentum transfer process which results in agitation of the particles and detachment from the substrate when the forces of agitation exceed the particle's adhesion forces. It has been found that particulate detachment is enhanced when the shockwave arrives at the substrate at an angle of between 30 and 45 degrees relative to the substrate surface.

The presence of capillary forces and particle deformation significantly increases the adhesion force between particle and substrate. In order to increase the efficiency of particle detachment due to the laser induced shockwave cleaning, ultraviolet energy is used to advantage to desorb the substrate surface thereby reducing the capillary forces and related particle adhesion.

Bearing in mind the problems and deficiencies of the prior art particulate removal processes, it is therefore an object of the presently described apparatus and method to provide improvements in contaminant removal from surfaces such as the substrate surfaces used in the manufacture of electronic components. A further objective is to use ultraviolet energy in removing organic contamination on substrate surfaces. Another objective is to provide a method and apparatus for using focused laser energy to create a shockwave for removing particles through a momentum transfer process. A further objective is to improve particulate removal by directing the shockwave at an acute angle to the substrate surface. It is another objective to provide a method and apparatus for removing contaminants from a substrate while preventing redeposition by sweeping detached particles to one side using a gas stream. Yet another objective is to provide a method and apparatus for removing targeted particulate from a substrate surface without the need to clean an entire substrate surface.

The details of one or more embodiments of these concepts are set forth in the accompanying drawings and the description below. Other features, objects, and advantages of these concepts will be apparent from the description and drawings, and from the claims.

### DESCRIPTION OF DRAWINGS

FIG. 1 is a schematic diagram of an example, in accordance with the present description, of a laser induced shockwave surface cleaning apparatus and is shown as an elevational view;

FIG. 2 is an example elevational view of a shockwave housing thereof in cross section showing a relationship between a laser beam, the housing and a substrate surface which may be placed on an angle relative to the housing;

FIG. 3 is a graphical illustration in elevation view thereof of an example of the manner in which particles that are released from the substrate surface tend to initially move in a revolving torus shaped gas stream;

FIG. 4 is a graphical illustration in elevation view thereof of an example of the manner in which particles that are released from the substrate surface are swept to one side by an injected gas stream; and

FIG. 5 is a logic diagram defining an example process of the presently described method.

Like reference symbols in the various drawings indicate like elements.

### DETAILED DESCRIPTION

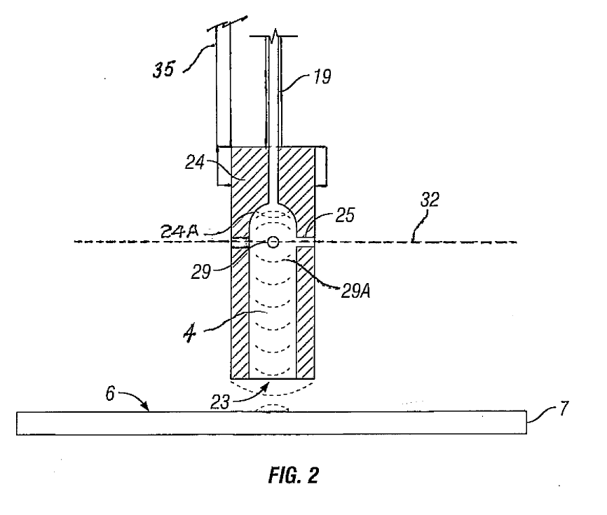

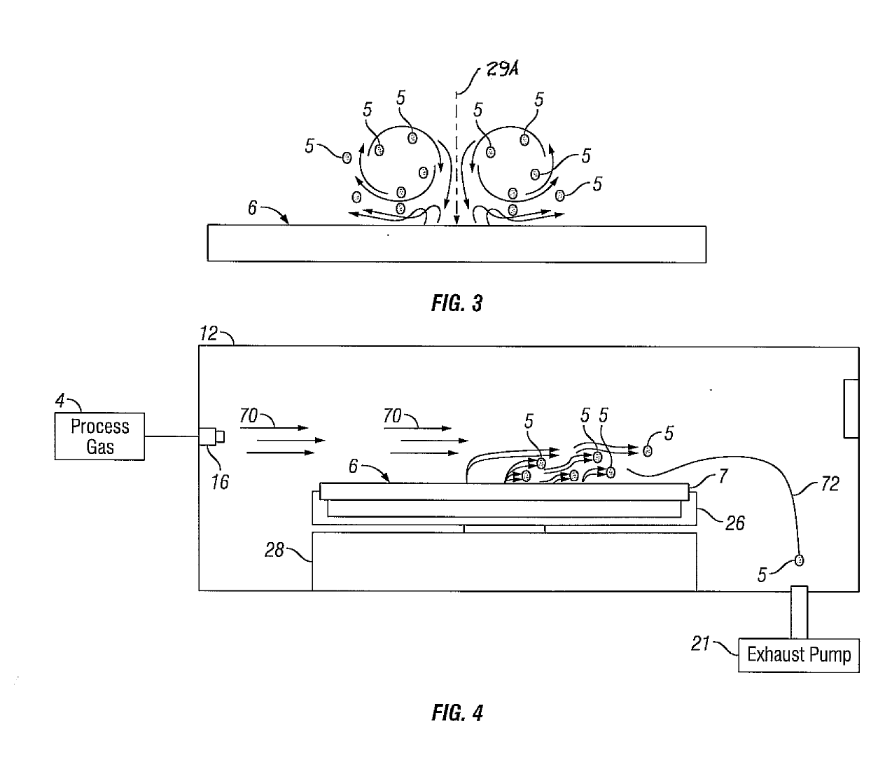

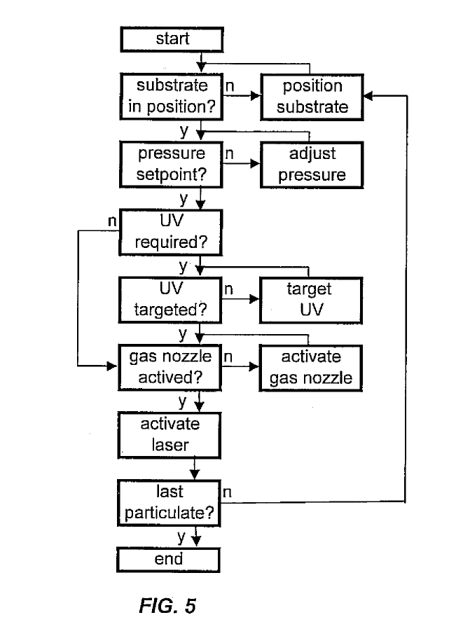

Photolithographic surfaces such as the surfaces of photomasks, semiconductor wafers, and optical elements associated with, for instance, printing microelectronic features are susceptible to defect and residue formation during processing. Such defects may include haze, crystal growth, ionic residues, and oxides among others. The term “substrate 7” as applied herein shall mean a wafer, a photomask, an optical element and any other article that may, by its nature and use, require the removal of micro-particles 5 from its surface 6, as shown in FIGS. 3 and 4. Substrates 7 may be of materials such as: quartz, metal, rubber, plastic, ceramic, and other organic or inorganic substances. The term “substrate surface 6” is applied herein to mean a surface of the substrate 7 that is generally planar, at least to micrometer dimensions, and able to be oriented facing generally upwardly as is shown in FIG. 2. The term “particle 5” is applied herein to mean any substance whatever that is foreign to the substrate 7 or foreign to the successful use of substrate 7, and may include discrete solid bits of metals and non-metals, organic materials, dusts and debris, liquid droplets and residues therefrom and other similar foreign materials which are well known in the semiconductor fabrication and optics arts as well as in related fields. The presently described method is applicable to particles 5 and agglomerations of particles 5 in the range of a few nanometers to a few hundreds of nanometers. The particles 5 that are found on substrate surfaces 6 may be secured typically by mechanical, electrical and chemical bonds. Some of these defects may be classified as organic contamination and are also referred to herein as particles 5 as well. The presently described methods address such particles 5 and their adherent forces.

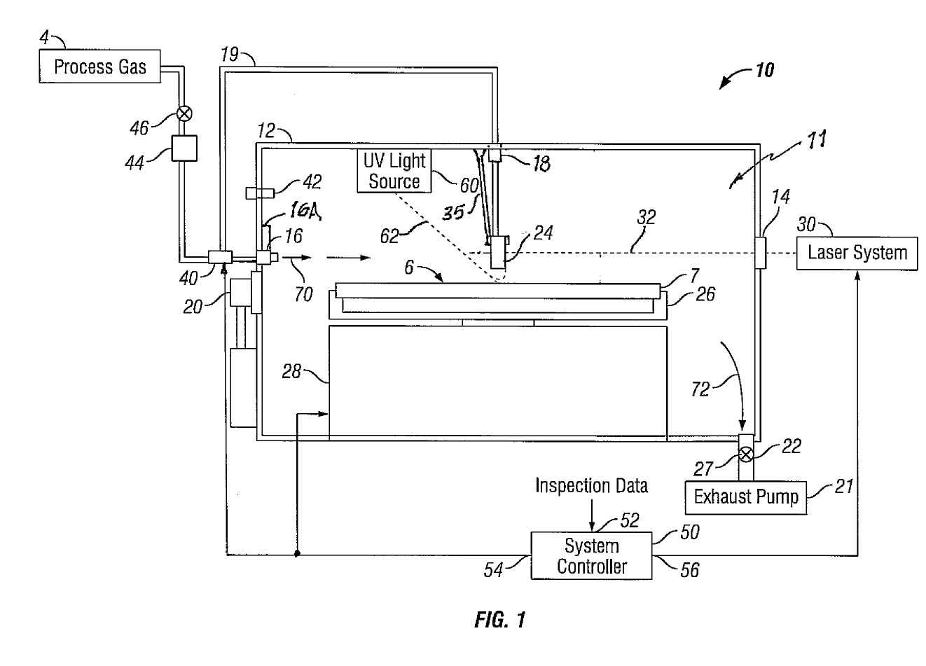

FIG. 1 shows the presently described apparatus 10 which is particularly adapted for removing particles 5 from a surface 6 of a substrate 7. The apparatus 10 may have a chamber 11 enclosed by chamber walls 12 which may support a window 14, a blower nozzle 16, a gas inlet 18, a transfer door 20, and an exhaust manifold 22. A shockwave housing 24, a substrate chuck 26 and a motorized stage 28 may be located within chamber 11. Chamber 11 may be at or near atmospheric pressure with N2 or air for instance. an atmosphere typically of a selected gas or gas mixture. Such chambers 11 are well known in the art. Chamber window 14, blower nozzle 16, gas inlet 18, transfer door 20, exhaust manifold 22, substrate chuck 26 and motorized stage 28 are components that are well known in the field of this disclosure and could be selected by those of skill in the art by routine steps. Chamber 11 may be accessed through transfer door 20. The gas inlet 18 is in gas communication with the shockwave housing 24 through conduit 19 which may be a stainless steel tube or a flexible tube. Process gas 4 may be used to supply one or more gas constituents directly to housing 24 in accordance with the presently described method. It is noted that fixture 35 secures housing 24 in place and allows housing 24 to be set at an angle relative to substrate 7. This can be accomplished by routine mechanical engineering approaches well known to those of skill in the art. Substrate 7 is always held with surface 6 horizontal and facing upwardly. An inert gas 4 such as Ar, Kr, N2, He, and Ne or a reactive gas such as H2, O2, O3, NF3, C2F6, F2 and CL2 may be used alone or in combination in the present process and the combination of Ar and He has been found to be particularly effective.

The transfer door 20 may be positioned and enabled for exchanging the substrate 7 with the substrate chuck 26 which can grip the substrate 7 by its edges or by suction, for example, as is well known in the art. Substrate transfers through such doors 20 is well known in the semiconductor and optics arts and are designed for maintaining the substrate 7 in a clean state during transfers, and also during manipulations in conjunction with the cleaning processes in general. The window 12 is made of a material that is transparent to the laser energy beam 32 used in the described method, and must be aligned with an entry channel 25 in housing 24 which may be in the range of 1 mm in diameter. It is pointed out, too, that channel 25 is formed clear through housing 24 so that beam 32 dos not impact housing 24, but only the process gas 4 within. Housing 24 may be made of a structural material such as stainless steel or quartz glass, capable of withstanding the explosive forces of shockwave 29A as will be described.

The blower nozzle 16 may be aligned with the substrate chuck 26 for directing a gas stream 70 as shown in FIG. 1 by arrows, from the blower nozzle 16 in parallel with the substrate surface 6 when the substrate 7 is secured and held in a preferred orientation by the substrate chuck 26. This gas flow 70 relative to surface 6 is best shown in FIG. 4. A megasonic transducer 16A may be engaged with blower nozzle 16 so that gas flow 70 is cavitated at between 800 and 4000 kHz with the energy released by transducer 16A. This cavitation helps to reduce a gaseous laminar boundary layer adjacent to the surface of substrate 7 and this enhances the ability of the sonic shockwave 29A to impact and remove particles 5. This also helps to prevent redeposition of particles 5, by delivering added gaseous floatation energy to particles 5 after they have been removed from surface 6 and are floating above it as shown in FIG. 3.

The motorized stage 28, preferably an X-Y-Z-e operating table may be able to position selected areas of surface 6 relative to a shockwave 29A as shown in FIG. 2. During the cleaning process, the motorized stage 28 is moved continuously to expose a local area of the substrate 7 to a continuing series of shockwaves 29A. The shockwave housing 24 may be located in a direct path between the blower nozzle 16 and the exhaust manifold 22 so that when particles 5 are liberated from selected areas of the substrate surface 6 they can be “blown,” by impingement of the gas stream 70, toward exhaust manifold 22 for exiting from chamber 11.

A laser system 30 may be positioned outside chamber 11 adjacent to window 14. Laser system 30 may include a laser beam generator and appropriate optics for expanding and focusing the beam 32. As shown in FIG. 2, beam 32 is directed through channel 25 and focused at area 29 within the shockwave housing 24. The impact of laser beam 32 on process gas 4 creates a rapid heating, ionization and expansion of the gas 4. As shown in FIG. 2, a high velocity shockwave 29A escapes housing 24 via outlet 23. The interior surface of housing 24 may include a reflecting surface 24A so that shockwave 29A carries most of the energy delivered to the gas 4 by laser beam 32.

A chamber pressure control instrument 40 and a gas flow control instrument, such as a mass flow controller 44 and a gas inlet valve 46 operate under control of a system controller 50 to maintain a desired chamber gas pressure and gas throughput within chamber 11. Such control is very well known in the art, and this description should be taken as only one possible example of the many approaches to gas pressure and gas flow control that are known. The system controller 50, which may be a computer, may have an inlet port 52 for receiving substrate inspection data and a first outlet port 54 for delivering instructions to the motorized stage 28 and to pressure control instrument 40, and a second outlet port 56 for delivering instructions to the laser system 30. Signals between these components are made using common data signal cables as is well known in the art. System controller 50 is enabled for instructing motorized stage 28 to move substrate chuck 26 and substrate 7 to position selected areas of substrate surface 6 immediately below shockwave outlet 23 and then for instructing laser system 30 to release laser beam 32 for producing the shockwave 29A. To enhance the laser induced shockwave formation and delivery to the surface 6, a heavy gaseous atomic species such as Ar or Kr is used in this process and just prior to the delivery of the laser beam 32 into housing 24, a steady stream of the process gas 4 is delivered to housing 24 from inlet 18 so that the pressure within housing 24 may be elevated at the time the incoming laser energy enters housing 24.

As shown in FIG. 1, an ultraviolet light source 60 may be positioned for directing ultraviolet energy 62 to the substrate surface 6. In conjunction with the energy 62 one or more of the above defined process gases 4 may be used to desorb surface 6. This process induces dissociation of certain gaseous species to produce one or more reactive gaseous components which reduces capillary forces between particles 5 and surface 6. The ultraviolet radiation 62 may be selected in a wavelength range of from about 140 to 400 nanometers at an intensity of about 1 mW/cm2 and preferably higher then 10 mW/cm2. Examples of ultraviolet sources 60 that are effective in this process include high-pressure mercury lamps (wavelength of about 250-480 nm), low-pressure mercury lamps (wavelength of about 180-480 nm), UV light emitting laser diodes (wavelength of about 300-400 nm), metal halide lamps (wavelength of about 200-400 nm), Xe2 excimer lamps (wavelength of about 172 nm), Ar excimer lamps (wavelength of about 146 nm), KrCl excimer lamps (wavelength of about 222 nm), Xel excimer lamps (wavelength of about 254 nm), XeCl excimer lamps (wavelength of about 308 nm), ArF excimer lasers (wavelength of about 193 nm), and KrF excimer lasers (wavelength of about 248 nm).

In an exemplary embodiment of the present method, the laser shockwave technique is employed for the removal of inorganic and metallic contamination, which we shall also refer to as particles 5. In order to generate a laser induced plasma shockwave 29A, a laser beam 32 may be generated by a Q-switched Nd:Yag laser with a fundamental wavelength of about 1064 nm. The laser beam 32 emerges from the laser system 30 where it has been expanded and focused by optics within the system 30. The expanded and focused laser beam 32 passes through an optically transparent gas tight window 14, which is mounted, on chamber wall 12. The laser beam 32 may be directed parallel to the substrate surface 6 as shown in FIG. 1, and through housing 24 thereby generating the laser-induced plasma and shockwave 29A. The shockwave 29A propagates rapidly and with explosive force out of housing 24 to impinge on substrate 7 and thereby removes inorganic and metallic surface contaminants, i.e., particles 5, which are adhered to the substrate surface 6. The power density of the laser beam 32 at its focus point 29 is preferably about 1012 W/cm2. The plasma shockwave 29A is the result of an intense electric field induced in the process gas 4 by the energy delivered by laser bean 32. The gas 4 is rapidly heated, ionized and expanded, thereby producing the plasma shockwave 29A which then propagates downwardly due to the confined space within the housing 24 and the reflective surface 27 within housing 24.

Using a 450 mJ laser, the delivered laser beam 32 has been found to be able to travel a distance of between 25 and 450 mm with appropriate effectiveness in the present process. The motorized stage 26 may be used to position the substrate 7 below the laser induced plasma shockwave exit 23 at a distance of between about 1 mm and 20 mm. In one application, the motorized stage 26 adjusts the z-axis height for a distance typically of about 5 mm from the exit point 23 of the housing 24 Due to the distance of the laser induced plasma 29 from the surface 6 shockwave pressure may be insufficient to remove particles 5 below about 50 nm in diameter. To increase the shockwave pressure sufficiently to overcome this problem, one or more of the above defined gases 4 may be used to generate a shockwave, Kr and particularly Ar gas shows higher pressures generated than other gases so that it is the preferred process gas in the presently described process. The interior surface of housing 24 may include a reflecting surface 24A so that shockwave 29A at outlet 23 carries most of the energy delivered to the process gas 4. To further enhance the cleaning efficiency the shockwave housing 24 may be rotated to a shallow angle, between 20-60 degrees and preferably 45 degrees relative to the horizontal. The configuration shown in FIG. 2 allows the use of a relatively lower power laser while generating a shockwave pressure sufficient to remove sub-50 nm sized particles.

In another aspect of the present method it is desired to prevent redeposition of particles 5 that have been already removed from the substrate surface 6. Referring to FIG. 3 the impinging shockwave 29A loosens and detaches particles 5 from the substrate surface 6. Once the particles 5 are detached from the substrate surface 6, the ionized gas stream behind the shockwave 29A traps the suspended particles 5 in a toroidal shaped revolving gas envelope at velocities of several m/s. Therefore, the complete removal of particles 5 takes place over a timescale of milliseconds. The toroidal shaped gas envelope that is formed and related particle movement geometry adjacent to the substrate surface 6 produces a high probability of particle redeposition onto surface 6 as shown in FIG. 3.

Referring to FIG. 4 the chamber inlet gas nozzle 16 produces a unidirectional gas stream 70 within chamber 11 as indicated by the horizontal arrows in FIGS. 1 and 4. This gas stream 70 may be injected so as to move parallel to the substrate surface 6, and, as a continuous flow over the substrate surface 6 which may have a velocity of 20 m/s for example. The gas stream 70 impinges on the ejected particles 5 sweeping them laterally away from the substrate surface 6. In this approach, the ejected particles 5 are prevented from re-contacting the substrate surface 6, but rather are forced to move laterally to be subsequently captured by exhaust pump 21. When gas stream 70 is injected with transfer door open, it has been found that the efficiency of the particle sweeping process is enhanced. This result can be obtained by venting the chamber in other ways as well in order to reduce resistance to entry of stream 70.

The specific locations of particles 5 on the substrate surface 6 may be identified by well known inspection procedures and the information data concerning these locations may be transferred to the system controller 50 via input port 52 as shown in FIG. 1. The system controller 50 may then move the substrate 7 to position these particle locations sequentially under the shockwave housing 24 for exposure to the shockwave 29A. To more efficiently accomplish the later, the substrate surface 6 may be associated with a virtual grid overlay as is well known in the art, and the particle locations then may be defined according to intersections on the grid overlay. For example, if during inspection a particle 5 is found on the substrate surface 6 at grid location X-26, Y-64; then, during the cleaning process, the system controller 50 directs the motorizing stage 28 to position the substrate so that location X-26, Y-64 is adjacent to the shockwave outlet 23 for exposure to the shockwave 29A. The gas species and gas pressure above the substrate surface 6 and within the shockwave housing 24 may be controlled also by controller 50 to maximize the shockwave effect on the removal of the particles 5.

A number of embodiments have been described. Nevertheless, it will be understood that various modifications may be made without departing from the spirit and scope of this disclosure. Accordingly, other embodiments are within the scope of the following claims.

What is claimed is:

1. An apparatus for removing particles from a substrate surface, the apparatus comprising:
a shockwave housing positioned for projecting a shockwave traveling at a selected angle toward the substrate surface;
the shockwave housing having an interior space, a through hole, and a shockwave outlet;
a laser system enabled for directing a laser beam through the through hole of the shockwave housing and for focusing the laser beam within the interior space;
wherein, impingement of the laser beam on a gaseous medium within the interior space produces the shockwave and delivers energy of the shockwave to the particles on the substrate surface.

2. The apparatus of claim 1 wherein the substrate is supported by a motorized stage enabled for moving selected portions of the substrate into positions for receiving a sequence of said shockwaves at each said selected portion.

3. The apparatus of claim 1 further comprising a gas system enabled for delivering a process gas into the interior space of the shockwave housing.

4. The apparatus of claim 1 wherein the shockwave housing has a reflector capable of directing the shockwave toward the substrate.

5. The apparatus of claim 1 further comprising an ultraviolet energy source positioned for directing ultraviolet energy to the substrate surface.

6. The apparatus of claim 1 wherein the combination of a selected output power level of the laser;
a distance from the through hole of the shockwave housing to the substrate surface; and
a species of the selected process gas;
results in removing particles of a size below 50 nm from the substrate while avoiding thermal damage to the substrate.

7. The apparatus of claim 1 further comprising a chamber having an interior atmosphere.

8. The apparatus of claim 1 further comprising a blower nozzle positioned for directing a gaseous flow across the substrate surface.

9. A method for removing particles from a substrate surface, the method comprising:
positioning a shockwave housing for projecting a shockwave traveling at a selected angle toward the substrate surface;
positioning a laser system for directing a laser beam through a through hole in the shockwave housing;
focusing the laser beam at a point within an interior space within the housing;
directing the shockwave housing out of a shockwave outlet of the shockwave housing;
impinging the shockwave on the substrate surface to deliver energy thereto.

10. The method of claim 9 further comprising moving selected portions of the substrate into positions for receiving a sequence of said shockwaves at each said selected portion.

11. The method of claim 9 further comprising delivering a process gas into the interior space of the shockwave housing.

12. The method of claim 9 further comprising reflecting the shockwave off of a reflector within the shockwave housing.

13. The method of claim 9 further comprising directing ultraviolet energy onto the substrate surface.

14. The method of claim 9 further comprising: selected an output power level of the laser; a distance from the through hole of the shockwave housing to the substrate surface; and a species of the selected process gas to enable removing particles of a size below 50 nm from the substrate surface while avoiding thermal damage to the substrate.

15. The method of claim 9 further comprising positioning a blower nozzle to direct a gaseous flow across the substrate surface.

16. A method for removing particles from a substrate surface comprising:
focusing a laser beam into a shockwave housing thereby ionizing a process gas therein;
developing a shockwave within the shockwave housing;
delivering the shockwave to the substrate surface to thereby dislodge and release particles adherent on the substrate surface; and
directing a vibrating gaseous stream parallel to the substrate surface and impinging the vibrating gas stream onto the dislodged particles and thereby driving the particles lateral to the substrate surface to avoid re-deposition of the particles on the substrate surface.

17. The method of claim 16 further comprising identifying specific locations of the particles on the substrate surface and moving the specific locations sequentially into position for receiving the shockwave.

18. The method of claim 16 wherein the shockwave is directed toward the substrate surface at an angle below 60° relative to the substrate surface.

19. The method of claim 18 wherein the shockwave is directed toward the substrate surface at an angle about 45° relative to the substrate surface.

20. The method of claim 16 wherein the process gas is one of Ar, a mixture of Ar and He, and a mixture of Ar with a chemically reactive gaseous species.
